(19) United States
(12) Patent Application Publication
(10) Pub. No.: US 2009/0196378 A1
(43) Pub. Date: Aug. 6, 2009

(54) POST CORRELATION SYSTEM FOR GNSS RECEIVER

(75) Inventor: Jui-ming Wei, Taichung City (TW)

Correspondence Address: KIRTON AND MCCONKIE, 60 EAST SOUTH TEMPLE,, SUITE 1800, SALT LAKE CITY, UT, 84111, US

(73) Assignee: MEDIATEK INC., Hsin-Chu (TW)

(21) Appl. No.: 12/023,295

(22) Filed: Jan. 31, 2008

(51) Int. Cl. H03D 1/00; H04L 27/06

(52) U.S. Cl. 375/340

(57) ABSTRACT

A post correlation system for a GNSS receiver uses an FFT engine to perform post-FFT operation to obtain spectrum data. The system has a contender selector for sieving magnitude results of the spectrum data meeting some specific conditions for selected hypotheses. The sieved magnitudes results rather than all the magnitude results are stored into a memory. By doing so, the requirement of the memory capacity can be significantly reduced.

### TECHNICAL FIELD OF THE INVENTION

The present invention relates to a GNSS (Global Navigation Satellite System) receiver, more particularly, to a post correlation system for a GNSS receiver using FFT (Fast Fourier Transform) techniques.

### BACKGROUND OF THE INVENTION

Fast Fourier Transform (FFT), which is well known in digital signal processing, has been applied in satellite communication, such as GNSS (Global Navigation Satellite System). For a GNSS receiver, TTFF (Time to First Fix), which generally means that at least four satellite are found for 3D positioning, is always a key issue for a user. To improve the performance of TTFF, a long period of integration for acquiring a satellite signal is undesirable. FFT solution provides powerful ability to improve correlation speed and signal acquisition and tracking performances.

To acquire a satellite, at least three domains must be considered. The three domains include visible satellites, code phases and Doppler frequency bins. A set of a specific satellite, a specific code phase and a specific Doppler frequency bin is called a hypothesis. The receiver detects the signal, which is spread-spectrum coded, from a specific satellite by correlating the signal with delayed versions of a spreading code (e.g. PRN (Pseudo Random Noise) code). If the correlation result is sufficiently high, it means that the receiver hits the satellite. This is called “acquisition”. After that, the receiver uses the delayed spreading code to achieve synchronization with the signal transmission from the satellite. This is called “tracking”. For a specific satellite and a specific Doppler frequency bin, a GPS receiver needs to search 1023 code phases, for example. Conventionally, correlations for the 1023 code phases are done in a TDM (Time Division Multiplexing) manner. As can be known, it will take a long time. In addition, due to noises and other interference, the accuracy and sensitivity of the receiver are influenced. It will be desirable if an additional process is provided after correlation to promote the receiver performances. FFT is a suitable solution to satisfy these requirements. FFT solution provides powerful correlating capability which is helpful in quick signal acquisition, but the huge memory requirement for post processing is a real burden in hardware cost.

### SUMMARY OF THE INVENTION

The present invention is to provide a post correlation system for GNSS receiver. The post correlation system comprises an FFT engine to conduct post-correlation FFT for selected hypotheses, so as to obtain spectrum data. The post correlation system has a magnitude calculation unit for calculating magnitude results of the spectrum data. Rather than storing all the magnitude results, the post correlation system has a contender selector for sieving specific magnitude results according to predetermined conditions. For example, the contender selector sieves the greatest ones of the magnitude results. Alternatively, the contender selector sieves the greatest one of the magnitudes results and the magnitude results of some points around the point corresponding to the greatest magnitude result.

By the present invention, requirement for memory capacity to store the magnitude results of the post-correlation FFT spectrums is reduced. Accordingly, the cost of memory can be greatly decreased.

### BRIEF DESCRIPTION OF THE DRAWINGS

FIG. 1 is a block diagram schematically and generally showing a GNSS receiver in accordance with a first embodiment of the present invention;

FIG. 2 is a flow chart generally showing main steps of a post correlation method in accordance with the present invention;

FIG. 3 is a block diagram schematically and generally showing a rear portion of a GNSS receiver in accordance with a second embodiment of the present invention;

FIG. 4 is a block diagram schematically and generally showing an embodiment of a contender selector in accordance with the present invention; and

FIG. 5 is a block diagram schematically and generally showing another embodiment of a contender selector in accordance with the present invention.

### DETAILED DESCRIPTION OF THE INVENTION

The present invention will be described in detail in conjunction with the appending drawings.

If sampling frequency for input data is 1.023 MHz, then 1023 data points are obtained every millisecond (ms). For a specific satellite and specific Doppler frequency bin, the signal data stream is transformed into frequency domain (FFT), correlations (multiplying and adding operations) for 1023 code phases are done at the same time, then the correlation results are converted back to time domain, which is known as IFFT (Inverse FFT). The effects of FFT correlation, which is referred to as pre-correlation FFT, and time domain correlation are equivalent. The time period for correlation is much shorter for pre-correlation FFT with the price of more power consumption in comparison with time-domain correlation. However, since rapid acquisition is essential for a GNSS receiver, pre-correlation FFT can be a desirable choice.

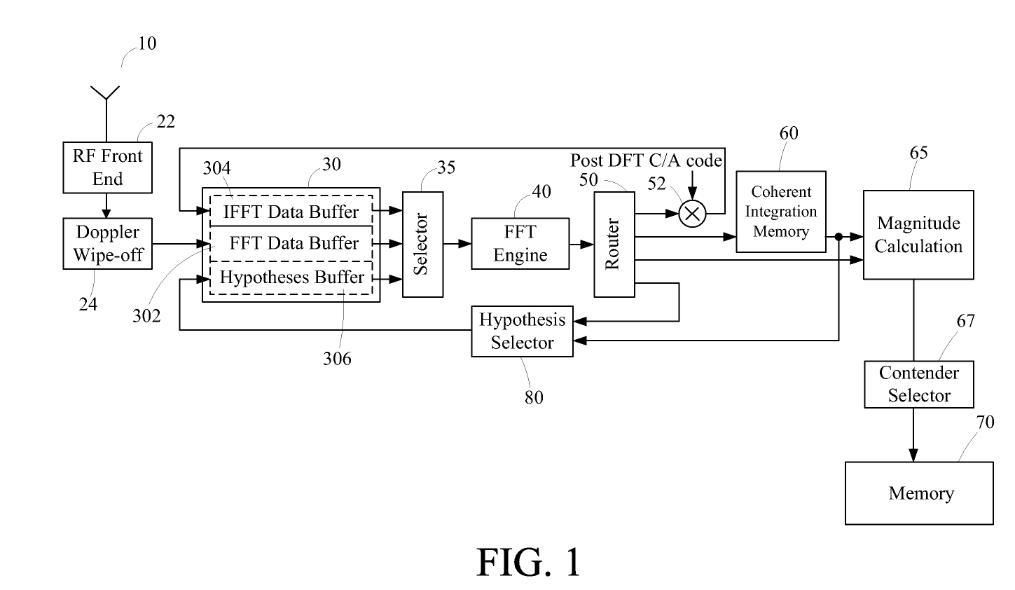

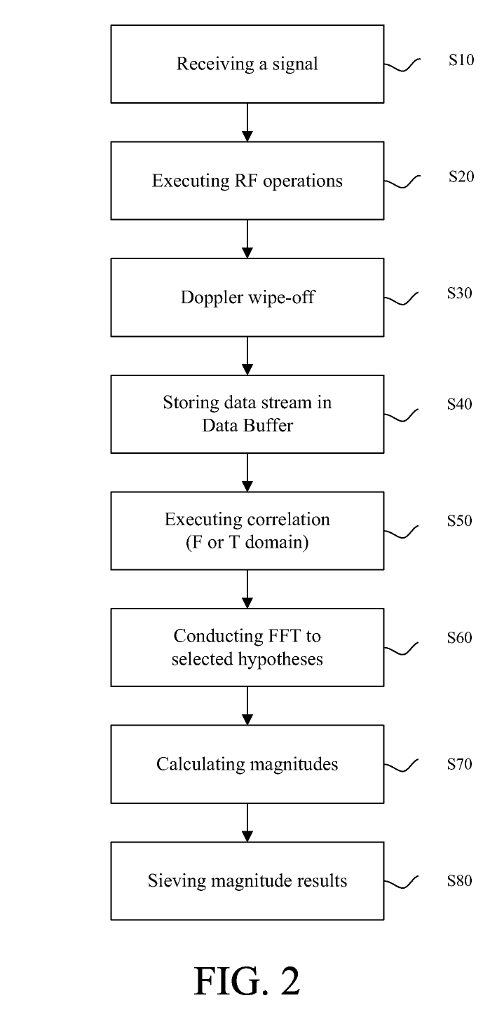

FIG. 1 is a block diagram schematically and generally showing a GNSS receiver having a post correlation system in accordance with a first embodiment of the present invention. FIG. 2 is a flow chart generally showing a post correlation method executed on the receiver. The receiver has an antenna 10 for receiving a signal for each hypothesis (step S10), a RF (radio frequency) front end 22 for executing RF related operations (step S20) mainly including down-conversion and digitization to a data stream of the signal. The receiver further has a Doppler wipe-off unit 24 for removing Doppler frequency component from the data stream (step S30). The resultant data stream is stored in a data buffer 30 (step S40). As can be seen from the drawing, the data buffer 30 is divided into three portions: FFT data buffer region 302, IFFT data buffer region 304 and hypothesis buffer region 306, in the present embodiment. Since the scale of FFT increases by power of two, for 1023 data points per ms, 1024-point memory capacity is required for the FFT buffer region 302. The data stream output from the Doppler wipe-off unit 24 is stored into the FFT data buffer region 302. A selector 35 is used for selecting to pick up data from which region of the data buffer 30. At this stage, the selector 35 selects the data stream stored in the FFT data buffer region 302 to transfer. The data steam picked up from the FFT data buffer region 302 is provided to an FFT engine 40. The FFT engine 40 is implemented by an FFT kernel, which can be divided into several sub-FFT units operating in parallel to increase throughput. The sub-FFT units are programmable to support different lengths of FFT operations. In addition to FFT operation, the FFT kernel can also perform IFFT operation by adjusting mainly a twiddle factor. The FFT engine 40 triggers FFT operation for the data stream from the FFT data buffer region 302. This is referred to as “pre-correlation FFT”. The FFT result is multiplied with PRN code replica, which is processed with DFT (Discrete Fourier Transform) operation and also has 1024 points, by a mixer 52 to obtain frequency-domain correlation data (step S50). In the present embodiment, the correlation is executed in frequency domain. However, time domain correlation can also be utilized, which will be described in another embodiment. The frequency-domain correlation data is then stored back to the data buffer 30 via a router 50. The frequency-domain correlation data is stored in the IFFT data buffer region 304 for successive processing. To convert the data stream into time domain, the selector 35 selects to output the data stored in the IFFT data buffer region 304 and passed it to the FFT engine 40. At this stage, the IFFT operation is triggered with the twiddle factors and coefficients in butterfly units of FFT being adjusted. The conversion between FFT and IFFT is well known, and therefore the descriptions thereof are omitted herein. The data processed with IFFT is the time-domain correlation data, which is referred to as “post correlation data” hereafter for the sake of description convenience. A correlator of the receiver is substantially implemented by means of the FFT engine 40 and the mixer 52 with the cooperation of the data buffer 30, selector 35 and the router 50.

The resultant IFFT data (i.e. the post correlation data) is stored in a coherent integration memory 60 via the router 50. A magnitude calculation unit 65 is used for incoherent integration of the coherent integration results. After hypotheses of one millisecond have been completely collected, a post-correlation FFT is triggered (step S60).

If the hypothesis, of which the post correlation data is calculated and stored into the coherent integration memory 60, is selected, the post correlation data thereof is also sent to the hypothesis buffer region 306 of the data buffer 30 via the router 50 and a hypothesis selector 80, which will be further described later. Preferably, the hypotheses around the correlation peak are considered to be collected. The code phase range and point number for post-correlation FFT depends on correlation magnitude distribution, frequency search range, resolution requirement and the like. The router 50 is used to arrange a route for the data stream so as to direct the data stream to the proper successive component, such as the mixer 52, coherent integration memory 60, magnitude calculation unit 65 or hypothesis selector 80. The router 50 and the selectors 35, 80 can be implemented by hardware or software controlled blocks. The router 50 and selectors 35, 80 are respectively controlled by hardware logic or a processor (not shown) of the receiver for the data paths according to time and channel multiplexing arrangements, for example.

If there are 1023 code phases to be tried for 1 ms, then correlation data for 1023 code phases are calculated for each ms. To promote receiver performance, it is preferred that points with the same code phase at different frequencies are collected to be analyzed. The code phase and the frequency construct a two dimensional hypothesis distribution. In frequency domain, 32 or 64 points of the same code phase are collected, for example. That is, those 32 or 64 hypotheses are selected. The post correlation data of the selected hypotheses is sent to be stored in the hypothesis buffer region 306 via the hypothesis selector 80. If the signal strength is weak, or the interested frequency range is narrow but frequency resolution requirement is high, it is preferred to collect the coherent integration result of the correlation data. That is, coherent integration of the hypotheses stored in the coherent integration memory 60 is used. For example, coherent integration results of every two ms for the same code phase are picked from the coherent integration memory 60 to be stored into the hypothesis buffer region 306 via the hypothesis selector 80. The hypothesis selector 80 selects to feed the post correlation data or the coherent integration result of the post correlation data to the hypothesis buffer 306.

The data of the selected hypotheses is then sent to the FFT engine 40 through the selector 35 to be processed with FFT operation, which is referred to as “post-correlation FFT”. The frequency spectrum of the data obtained by the post-correlation FFT is stored into a memory 70. The memory is used as a spectrum memory for storing the spectrum and as an incoherent integration memory. Alternatively, the memory 70 is used only as a spectrum memory. In some circumstances, the memory 70 can store only the post-correlation spectrums, since the correlation peak and correct code phase can be derived from the spectrums. However, the spectrum (i.e. FFT result) is quite huge data, which occupies a great capacity of memory. The required memory size is derived as selected hypothesis number×point number×data bit length. As described, a two dimensional search is needed to search for the peak value to determined the correct code phase and Doppler frequency. In accordance with the present invention, to reduce the requirement of the memory capacity, only the spectrum results of the top N results of the spectrum magnitudes calculated by the magnitude calculation unit 65 are stored in the memory 70 rather than all the data. Alternatively, in addition to the peak result, only N-1 results around the peak result are stored. If the FFT point number is M, then the memory requirement is reduced to N/M. In addition, the search can be mainly focus on code-phase dimension, so as to improve searching efficiency. For example, as the post-correlation FFT outputs are generated, only the top two or three spectrum results are stored with the frequency bin indices thereof. By doing so, the memory capacity requirement is reduce, while information for handling multi-tone jammer, for example, still remains. Further more, successive processing load is reduced, since the data range to be processed is narrowed. Accordingly, power consumption can be decreased. The sieving of the top N results is executed by a contender selector 67, which is connected between the magnitude calculation unit 65 and the memory 70. That is, the magnitude calculation unit 65 calculates a magnitude for the post-correlation FFT result (step S70), and the contender selector 67 sieves a predetermined number of magnitude results calculated by the magnitude calculation unit 65 (step S80), as described above. As mentioned, the magnitude calculation unit 65 is used to calculate a magnitude from the spectrum, so that a peak can be found to determine whether signal acquisition is achieved, for example. The magnitude calculation unit 65 calculates the magnitudes for the coherent integration result from the coherent integration memory 60 for incoherent integration and the spectrum obtained by the post-FFT in a TDM manner.

As described above, the FFT engine 40 is shared for pre-correlation FFT/IFFT and the post-correlation FFT. In addition, different channels can share the same FFT engine 40. The sharing scheme can be implemented in a time multiplexing manner (e.g. TDM). The TDM sequence for the pre-correlation FFT, IFFT and post-FFT is adjustable to optimize the performance or as required. If the FFT engine 40 is shared between acquisition mode and tracking mode, the collection trends, especially for the post-correlation FFT, are different. In acquisition mode, it is necessary to search a wide code phase range, but for a specific code phase, the collected points can be less. In tracking mode, the code phase is substantially determined, so there is no need to search a wide code phase range. For the determined small code phase range, more points can be collected to achieve a better performance.

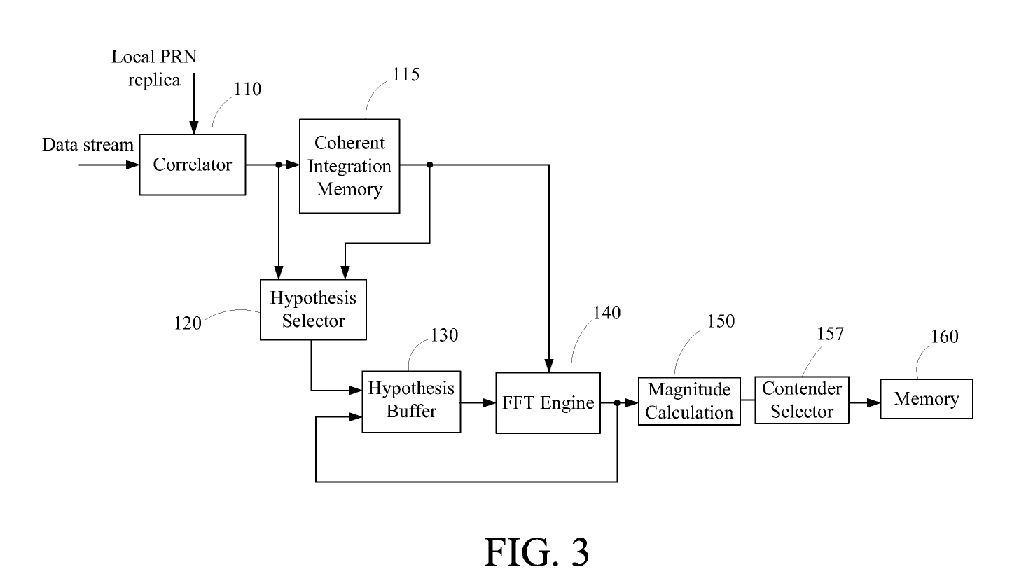

The post-correlation FFT can also cooperate with time-domain correlation. FIG. 3 is a block diagram schematically and generally showing a rear portion of a GNSS receiver in accordance with a second embodiment of the present invention. In FIG. 3, the components before a time-domain correlator 110, such as antenna, RF front end and Doppler wipe off unit connected therewith, are omitted for simplicity and clarity. In the present embodiment, the receiver has the time-domain correlator 110. The correlator 110 executes correlation operations to an input data stream, which has been down-converted and digitized, with delayed versions of a local PRN code replica for each hypothesis in a TDM manner, as well known in this field. The correlation result of each hypothesis is accumulated in a coherent integration memory 115 for coherent integration. If the hypothesis is selected, the correlation result thereof is also passed to a hypothesis buffer 130 as a point via a hypothesis selector 120. As in the first embodiment, the hypothesis selector 120 can also select to pass coherent integration results to the hypothesis buffer 130 if the signal strength is weak or for other considerations.

The data stored in the hypothesis buffer 130 is sent to an FFT engine 140, which can be implemented by an FFT kernel. The FFT engine 140 executes FFT operation to the data so as to generate post-correlation FFT data, that is, spectrums of the hypotheses, which can be referred to as post-correlation spectrums. To determine a correlation peak, it is necessary to calculate magnitudes of the spectrums by a magnitude calculation unit 150, which is also shared to calculate magnitudes of the coherent integration results from the coherent integration memory 115 for incoherent integration. The spectrums obtained from the FFT engine 140 and the calculated magnitudes thereof are stored in a memory 160, which is used as a spectrum memory. The memory 160 can also be used as an incoherent integration memory for accumulating coherent integration results at the same time. Information for signal acquisition and tracking can be derived from the post-correlation spectrum. Therefore, the post-FFT provides the benefits to promote the receiver performance. As the first embodiment, a contender selector 157, which is the same as the contender selector 67 is FIG. 1, is used to sieve top N results of the spectrum data so as to reduce memory capacity requirement and processing load.

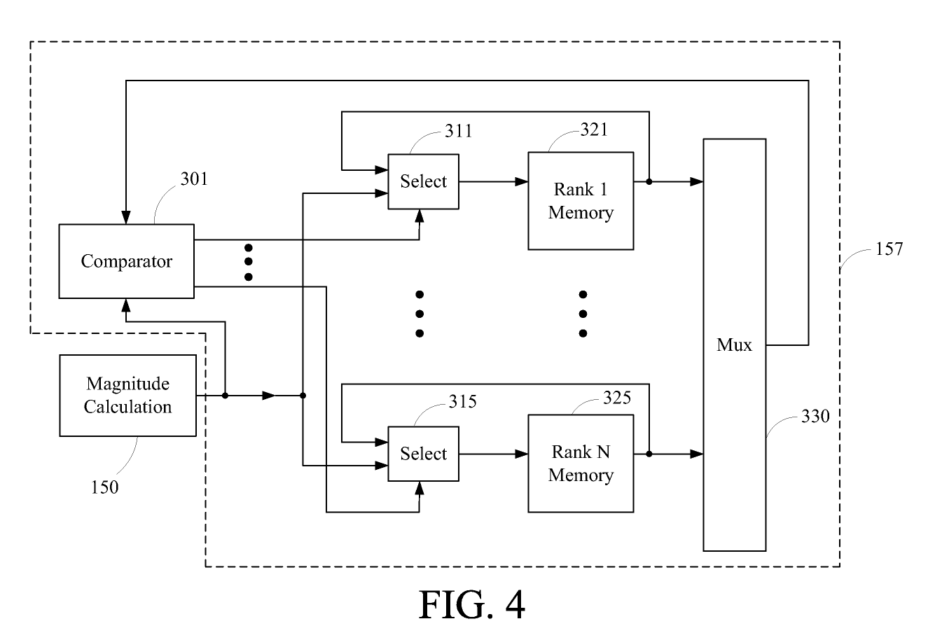

An example of implementation of the contender selector 157 (or 67) is shown in FIG. 4. The case that the top N results of the FFT spectrum are sieved is described now. As shown, the contender selector 301 has a comparator 301, a plurality of select units (only two are shown 311, 315, a corresponding number of rank memories (only two are shown) 321, 325, and a multiplexer 330. The rank memories Rank 1 memory 321 to Rank N memory 325 are used to store results from the magnitude calculation unit 150 in an order from the greatest to the least of the N stored results. The comparator 301 receives a magnitude result from the magnitude calculation unit 150 (or 65), compares the received result with the values stored in the Rank 1 memory 321 to Rank N memory 325 in sequence. Once the received result is greater than the result stored in one of the rank memories, the comparing operation is stopped. For example, if an incoming result is greater than the result stored in Rank 1 memory 321, then the comparing operation is stopped. That is, the respective comparing operations between the incoming result and the results stored in Rank 2 memory (not shown) to Rank N memory 325 are omitted. The corresponding select unit 311 selects the greater result, that is, the incoming result to update Rank 1 memory 321. Each select unit is controlled by the comparator 301 to select the incoming magnitude result or the magnitude originally stored in the corresponding rank memory and stores the selected one in the rank memory. The multiplexer 330 controls the comparator 301 to sequentially execute comparing operations for an incoming result with the results stored in the rank memories in a TDM manner.

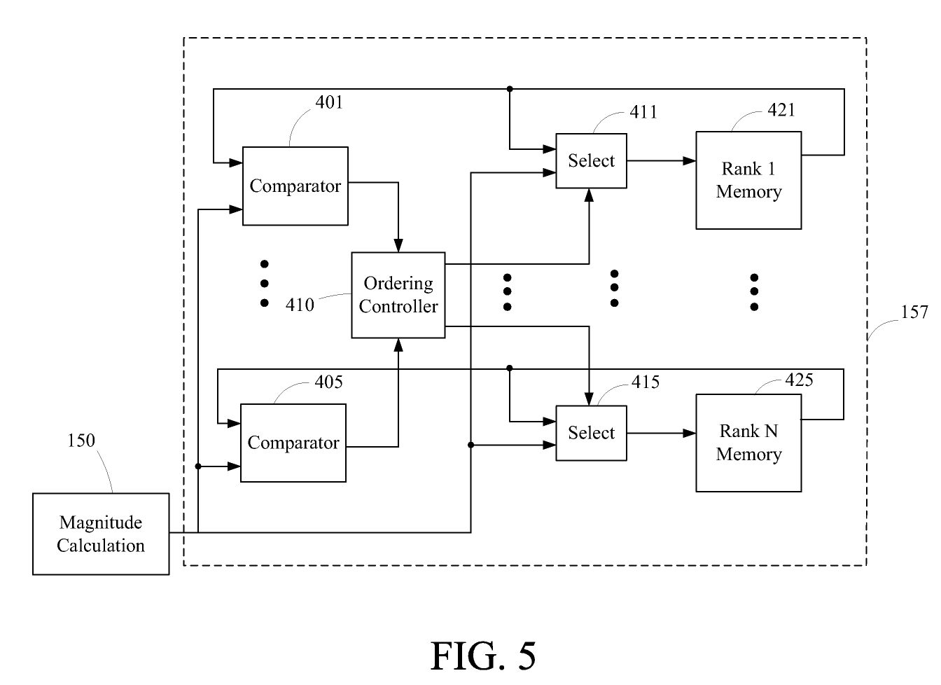

The contender selector can also be implemented as a contender selector 157′ shown in FIG. 5. The contender selector 157′ includes a plurality of comparators (only comparators 401, 405 are shown), and ordering controller 410, a plurality of select units (only select units 411, 415 are shown), and a plurality of rank memories (only Rank 1 memory 421, Rank N memory 425 are shown). Different from the contender selector 157 of FIG. 3, the contender selector 157 compares an incoming result from the magnitude calculation unit 150 (or 65) with data stored in the rank memories, respectively, by the comparators 401˜405. The ordering controller 410 checks if the incoming result is greater than any of the results stored in the rank memories. If the incoming result is greater than more than one rank memory result, the ordering controller 410 controls the corresponding select unit to update the rank memory with the highest priority. For example, if the incoming result is greater than the results stored in Rank 1 memory 421 and Rank 2 memory (not shown), then the ordering controller 410 instructs the select unit 411 to select and pass the incoming result so as to update the stored content of Rank 1 memory 421.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A post correlation system for a Global Navigation Satellite System (GNSS) receiver comprising:
a correlator for executing correlation operation to a data stream;
an FFT engine conducting FFT operation to a selected hypothesis of the data stream to generate a post-correlation FFT result thereof;
a magnitude calculation unit for calculating a magnitude for the post-correlation FFT result;
a contender selector for sieving a predetermined number of magnitude results calculated by the magnitude calculation unit; and
a memory storing the magnitude results sieved by the contender selector.

2. The post correlation system of claim 1, wherein the contender selector sieves the predetermined number of greatest ones of the magnitude results.

3. The post correlation system of claim 1, wherein the contender selector sieves the predetermined number of magnitude results which includes the greatest one and the magnitude results of points of the post-correlation FFT result around the point with the greatest magnitude result.

4. The post correlation system of claim 1, wherein the correlator comprises the FFT engine and a mixer, the FFT engine executes FFT operation to the data stream from the FFT data buffer to generate a pre-correlation FFT result and the mixer correlates the pre-correlation FFT result with a code converted into frequency domain to generate a frequency-domain correlation result, the FFT engine further executes IFFT operation to the frequency-domain correlation result to generate post correlation data.

5. The post correlation system of claim 1, wherein the contender selector comprises a plurality of rank memories for respectively storing magnitude results; a comparator for comparing an incoming magnitude result with the magnitude results stored in the rank memories so as to update the magnitude result stored in a specific one of the rank memories when the comparison result of the comparator meets a predetermined condition.

6. The post correlation system of claim 5, wherein the comparator stops comparing when the incoming magnitude is greater than the magnitude result stored in one of the rank memories.

7. The post correlation system of claim 5, wherein the contender selector further comprises a multiplexer for controlling the comparator to sequentially compare the incoming magnitude result with the magnitude results stored in the rank memories.

8. The post correlation system of claim 7, wherein the contender selector further comprises a plurality of select units respectively connected with the rank memories, each select unit is controlled by the comparator to select the incoming magnitude result or the magnitude stored in the corresponding rank memory to be stored in the rank memory.

9. The post correlation system of claim 1, wherein the contender selector comprises a plurality of rank memories for respectively storing magnitude results; a plurality of comparators for respectively comparing an incoming magnitude result with the magnitude results stored in the rank memories so as to update the magnitude result stored in a specific one of the rank memories when the comparison result of the comparator meets a predetermined condition.

10. The post correlation system of claim 9, wherein the contender selector further comprises an ordering controller determining to update which one of the rank memories according to the comparison results of the respective comparators.

11. The post correlation system of claim 9, wherein the contender selector further comprises a plurality of select units respectively connected with the rank memories, each select unit is controlled by the ordering controller to select the incoming magnitude result or the magnitude stored in the corresponding rank memory to be stored in the rank memory.

12. A post correlation method for a Global Navigation Satellite System (GNSS) receiver, said post correlation method comprising:
executing correlation operation to a data stream;
conducting FFT operation to a selected hypothesis of the data stream to generate a post-correlation FFT result thereof;
calculating a magnitude for the post-correlation FFT result; and
sieving a predetermined number of magnitude results calculated by the magnitude calculation unit.

13. The post correlation method of claim 12, wherein the predetermined number of greatest ones of the magnitude results are sieved in the sieving step.

14. The post correlation system of claim 12, wherein the predetermined number of magnitude results which includes the greatest one and the magnitude results of points of the post-correlation FFT result around the point with the greatest magnitude result are sieved in the sieving step.

15. The post correlation method of claim 12, the step of executing correlation comprises executing FFT operation to the data stream to generate a pre-correlation FFT result, correlating the pre-correlation FFT result with a code converted into frequency domain to generate a frequency-domain correlation result, and executing IFFT operation to the frequency-domain correlation result to generate post correlation data.

16. The post correlation method of claim 12, wherein the sieving step comprises respectively storing magnitude results; comparing an incoming magnitude result with the stored magnitude results so as to update the magnitude result stored in a specific one of the stored magnitude results when the comparison result of the comparator meets a predetermined condition.

17. The post correlation method of claim 16, wherein the comparing is stopped when the incoming magnitude is greater than one of the stored magnitude results.

18. The post correlation method of claim 16, wherein the comparing is controlled to sequentially compare the incoming magnitude result with the stored magnitude results.

19. The post correlation method of claim 12, wherein the sieving step comprises respectively storing magnitude results; respectively comparing an incoming magnitude result with the stored magnitude results so as to update a specific one of the stored magnitude results when the corresponding comparison result meets a predetermined condition.

20. The post correlation method of claim 19, wherein the sieving step further comprises determining to update which one of the stored magnitude results according to the respective comparison results.
